(19) United States
(12) Patent Application Publication
(10) Pub. No.: US 2011/0084303 A1
(43) Pub. Date: Apr. 14, 2011

(54) RADIANT HEAT STRUCTURE FOR PIN TYPE POWER LED

(76) Inventors: Yeon Su Cho, Yongin-si (KR); Chang Won Lee, Cheonan-si (KR); Kyung Min Cho, Suwon-si (KR)

(21) Appl. No.: 12/865,388

(22) PCT Filed: Jan. 30, 2009
(86) PCT No.: PCT/KR09/00474

§ 371 Date: Dec. 21, 2010

(30) Foreign Application Priority Data
Jan. 30, 2008 (KR) 10-2008-0009835

(51) Int. Cl. H01L 33/64; H01L 33/62

(52) U.S. Cl. 257/99; 257/712; 257/E33.075; 257/E33.066

(57) ABSTRACT

The present invention relates to the heat-radiation structure of a pin-type power Light Emitting Diode (LED). The heat-radiation structure includes an LED device, first and second lead frames, a mold unit, and a heat sink. The first lead frame is electrically connected to the LED device, and extended forward to the outside in order to supply power to the LED device. The second lead frame is provided to face the first lead frame, and extended forward to the outside. The mold unit includes the LED device, and molds the upper portions of the first and second lead frames out transparent material. The heat sink is provided at a bottom of the mold unit so that the lead frames penetrate therethrough, fixed into any of the two lead frames, and configured to receive heat from the lead frame which comes into contact therewith and to radiate the heat to the outside.

### BACKGROUND OF THE INVENTION

1. Field of the Invention

The present invention relates generally to the heat-radiation structure of a pin-type power Light Emitting Diode (LED) which has been used for cars, lighting, and billboards, and, more particularly, to the heat-radiation structure of a pin-type power LED, which efficiently radiates generated heat through lead frames connected to an LED chip, so that the life span of element devices is extended, which minimizes variation in the properties of elements attributable to heat and increases the application of current, so that radiation efficiency is improved, and which can be applied to existing LED manufacturing processes, so that the manufacturing cost can be tremendously reduced.

2. Description of the Related Art

LEDs are semiconductor p-n junction devices and light-emitting semiconductors which convert electrical energy into light energy. With regard to the operational principle of a general LED, when voltage is applied between terminals, current flows and electrons are combined with holes around p-n junction or an activation layer, so that light is emitted, thereby implementing various colors (wavelengths) depending on variation in the energy band gap which indicates the unique property of a semiconductor.

The materials of a general LED are classified into a direct transition semiconductor and an indirect transition semiconductor.

The indirect transition semiconductor includes horizontal transition attributable to heat and vibration, so that it is not suitable for realizing optimal radiation transition. The direct transition semiconductor is realized with radiation, so that it is often used as the material in an LED.

In the beginning of the development of LEDs in which indirect transition semiconductor crystals did not exist in a desired luminous region, the luminous region has been adjusted in such a way that specific impurities were added to indirect transition semiconductors and emission wavelengths were varied. However, direct transition semiconductors should be essentially used in order to realize high-brightness LEDs.

The technology in LED field may be largely divided into a chip manufacturing technology, the chip being the origin of a source of light, and a packaging technology which enables the chip to be used for a desired purpose.

Due to the short history of the LED field and the demand for power which could not be met, the development of the chip manufacturing technology, used to promote the efficiency of converting applied current into maximum light, has been the main problem in the development of technology in the meantime. Recently, with efforts through a large amount of technical progress together with the rapid growth of the LED industry, the improvement of the performance of LEDs using chips has reached a predetermined level, and methods of promoting light coupling efficiency by improving packages have been actively developed recently.

The functions of such an LED package may include electrical connection to the outside, protection for mechanical, electrical, and environmental factors from the outside, heat radiation, increase in luminescence efficiency, and the optimization of directivity.

Further, materials used for packaging may include metal stems, lead frames, ceramics, and printed substrates (PC prints). The materials may be coated with resin or not.

Generally, LED chips are mounted on lead frames plated with silver (Ag) in many cases.

This process is called die bonding, and conductive resin, with which silver or gold is mixed, is used to bond the LED chips or dies to a base.

The LED chips are fixed using the above-described method, and then the connection of lower electrodes is realized. The packaging is completed in such a way that connection of upper electrodes is generally realized by connecting a small wire made of gold using thermal compression or ultrasonic waves, and molding is performed using resin.

LED packaging products may be divided into two types, that is, insert-type/through hole-type LEDs (which are mounted in such a way that leads are inserted into holes and then soldered), which have been conventionally used, and into Surface Mount Device (SMD)-type LEDs (which are referred to as SMD-type LEDs and are mounted using Surface Mount Technology (SMT)) which have been rapidly and recently used.

The insert-type LEDs are divided into lamp-type LEDs and 4-pin LEDs (also, referred to as “Piranha-type LEDs”), and have progressed in correspondence to the SMD-type LEDs using excellent directivity properties and low amounts invested.

The improvement of the directivity of the lamp-type LEDs and 4-pin LEDs has progressed with the development of the large-size screens of LED electric bulletin boards and development of indirect lighting and indicators. If only the directivity in a horizontal direction is improved when a large-sized display is formed, the output of a single LED can be utilized to the utmost.

This can be applied to fields, such as stoplights, turn lights, lighting, and indicators, which are used in the field of automotive electricity in the same way.

The core technology of the above-described LED packaging process includes structure design from a chip level, optical design, thermal design, and packaging process technologies. The design of heat radiation capable of maximizing heat emission is the most important technology from among these.

An obvious tendency in recent high power LED packaging is to consider heat radiation measures and improve external quantum efficiency using the heat radiation measures as a core technology to be developed.

The development of a typical heat radiation technology may be to improve heat-emission properties which cause the transformation of lead frames.

Typically, in the case of LED lamps, the rated driving current thereof is generally 20 mA. However, recently, products, which are designed to easily emit heat by improving the rated driving current and enable a rated driving current of 50 mA to 60 mA to flow, and products, which enable an applied driving current of 30 to 50 mA to increase an applied driving current of 30 to 100 mA by increasing the heat emission of 4-pin LEDs, have been developed.

Another method of emitting heat includes a method of configuring a slug the thermal resistance of which is very small so that heat can be directly emitted from chips which generate heat, thereby increasing the properties of heat radiation, and a method of directly attaching a heat sink on a region which generates heat, which is mainly used for a driving current of 300 mA or more.

However, such a method requires that a new tool be developed instead of using existing tools, and has a tendency to be developed for products which can be used for high power packaging. However, the method has a problem in that it obstructs the creation of a new market because of an economic problem attributable to the rapid increase in manufacturing costs.

Further, the development of a packaging technology for shortening the path of the emission of heat generated from chips so that more amount of power can be applied has been completed or progressed in such a way that a package structure in which an aluminum substrate is used to efficiently radiate heat generated from LED chips has been developed, and an array-type packaging technology in which a plurality of LED lamps are formed on a single aluminum substrate has been applied.

However, there are problems in that reinvestment in production equipment and process production is requested due to the lack of compatibility with existing products, that different types of products are requested depending on the purpose thereof due to frequent change in the purpose of use, and that it is not economical since the prices of LED products are far more expensive than those of existing products due to the manufacturing costs of heat sinks, so that it is difficult to put to practical use, and that the demand thereof is limited even though the packaging technology has been put to practical use.

### SUMMARY OF THE INVENTION

Accordingly, the present invention has been made keeping in mind the above problems occurring in the prior art, and an object of the present invention is to provide the heat sink of a pin-type LED, which minimizes reliability-related problems generated because a current equal to or greater than a specific level cannot be applied due to heat generated when LEDs are turned on, so that LED chips deteriorate, and which can be easily applied to various types of application fields and can use existing packaging products, so that mass production is obtained based on minimum investment and compatibility, thereby increasing economic efficiency.

In order to accomplish the above object, the present invention provides a heat-radiation structure of a pin-type power Light Emitting Diode (LED) including: an LED device; a first lead frame electrically connected to the LED device, and extended forward to the outside in order to supply power to the LED device; a second lead frame provided to face the first lead frame, and extended forward to the outside; a mold unit configured to include the LED device, and to mold the upper portions of the first and second lead frames out of transparent material; and a heat sink provided at the bottom of the mold unit so that the lead frames penetrate therethrough, fixed into any of the two lead frames in an insertion manner, and configured to receive heat from the lead frame which comes into contact therewith and to radiate the heat to the outside.

When ends of the first and second lead frames are fixed to a substrate, the heat sink includes a protrusion portion formed in such a way that one end of the heat sink is extended, penetrated through the substrate, and protruded out from the rear side of the substrate.

The heat-radiation structure further includes a coupling portion at one end of the protrusion portion, the coupling portion being coupled to a heat sink member in a filling shape or a plate shape which is provided on the rear side of the substrate.

The heat sink includes: a plurality of heat sink slices respectively coupled to the first and second lead frames in the insertion manner while corresponding to the first and second lead frames; and a non-conductive member provided between each of the heat sink slices.

The present invention provides a heat-radiation structure of a pin-type power LED including: an LED device; a first lead frame electrically connected to the LED device, and extended forward to the outside in order to supply power to the LED device; a second lead frame provided to face the first lead frame, and extended forward to the outside; a mold unit configured to include the LED device, and to mold upper portions of the first and second lead frames out of transparent material; and two heat sinks each provided with longitudinal holes to which the first and second lead frames are respectively accommodated so that the first and second lead frames are inserted thereinto from both sides of a bottom of the mold unit, fixed using the respective lead frames in the state in which the two heat sinks are spaced apart from each other at a predetermined interval, and configured to receive heat from the lead frames which respectively come into contact therewith and radiate the heat to the outside.

When ends of the first and second lead frames are fixed to a substrate, the ends of the first and second lead frames are bent and extended at the bottom of each of the heat sinks and mounted on an upper portion of the substrate.

When two or more LED devices are arranged in a plurality of rows on the substrate, the heat sinks are provided to face each other so that the lead frames are electrically divided, and an insulation member is provided to connect two ends of the heat sinks.

Each of the heat sinks is made of using any one selected from among copper, aluminum, and iron.

Each of the heat sinks includes prominences/depressions around external edge thereof in order to increase heat radiation area.

### BRIEF DESCRIPTION OF THE DRAWINGS

The above and other objects, features and other advantages of the present invention will be more clearly understood from the following detailed description taken in conjunction with the accompanying drawings, in which:

FIG. 1 is a perspective view according to the present invention;

FIG. 2 is a longitudinal cross-sectional view according to the present invention;

FIG. 3 is the plan view of FIG. 2;

FIG. 4 is a longitudinal cross-sectional view according to a second embodiment of the present invention;

FIG. 5 is the plan view of FIG. 4;

FIG. 6 is a plan view showing the heat sink of FIG. 5;

FIG. 7 is the side view of FIG. 6;

FIG. 8 is the front view of FIG. 6;

FIG. 9 is a longitudinal cross-sectional view according to a third embodiment of the present invention;

FIG. 10 is the plan view of FIG. 9;

FIG. 11 is a plan view showing the heat sink of FIG. 10;

FIG. 12 is the side view of FIG. 11;

FIG. 13 is the front view of FIG. 11;

FIG. 14 is a longitudinal cross-sectional view according to a fourth embodiment of the present invention;

FIG. 15 is the plan view of FIG. 14;

FIG. 16 is a perspective view showing the heat sink of FIG. 15;

FIG. 17 is a longitudinal cross-sectional view according to a fifth embodiment of the present invention;

FIG. 18 is a longitudinal cross-sectional view showing the right side of FIG. 17;

FIG. 19 is the plan view of FIG. 17;

FIG. 20 is a perspective view showing the heat sink of FIG. 19;

FIG. 21 is a longitudinal cross-sectional view according to a sixth embodiment of the present invention; and

FIG. 22 is the plan view of FIG. 21.

### DESCRIPTION OF THE PREFERRED EMBODIMENTS

Reference now should be made to the drawings, in which the same reference numerals are used throughout the different drawings to designate the same or similar components.

Embodiments of the present invention will be described in detail with reference to the attached drawings below.

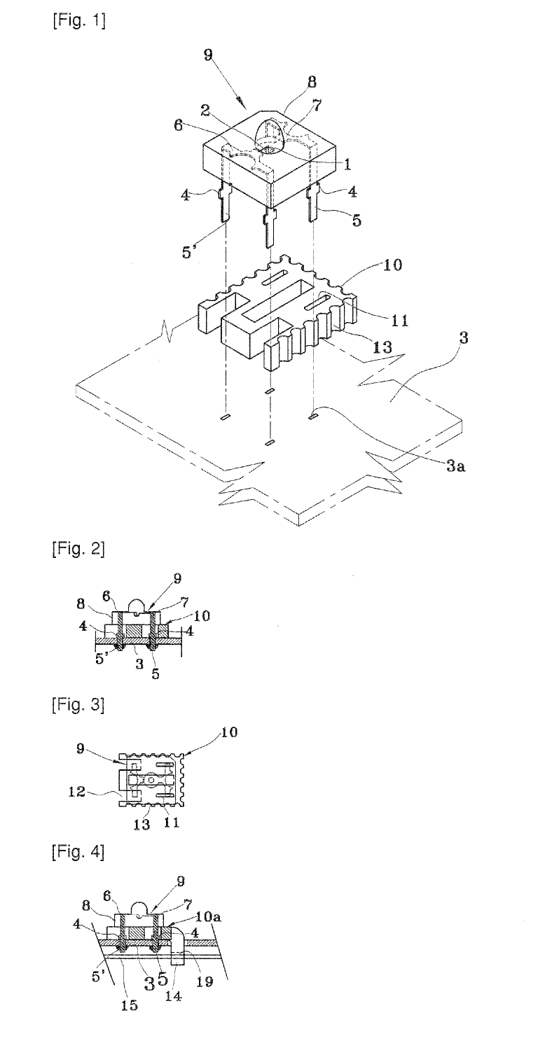

FIG. 1 is a perspective view according to the present invention, FIG. 2 is a longitudinal cross-sectional view according to the present invention, and FIG. 3 is the plan view of FIG. 2.

As shown in FIGS. 1 to 3, the heat-radiation structure of a pin-type power LED of the present invention includes an LED device 1; a first lead frame 7 electrically connected to the LED device 1, and configured to include a plurality of leads 5 extended forward to a substrate 3 in order to supply power to the LED device 1; a second lead frame 6 provided to face the first lead frame 7, and configured to include a plurality of leads 5′ extended forward to the substrate 3; a mold unit 8 configured to include the LED device 1, and to mold the upper portions of the first and second lead frames 7 and 6 out of transparent material; and a heat sink 10 provided in the space between the mold unit 8 and the substrate 3 so that each of the leads 5 and 5′ of the first and second lead frames 7 and 6 penetrates therethrough, and configured to come into contact with the leads 5 of the first lead frame 7 in order to receive heat generated by the LED device 1 and to radiate the heat to the outside.

The LED device 1 is seated on a seating depression extended from the first lead frame 7, and configured to supply power from the outside to the first lead frame 7 through the leads 5.

The first and second lead frames 7 and 6 may or may not have stoppers 4 at one ends of the leads 5 and 5′.

With regard to the first and second lead frames 7 and 6 which have the stoppers 4 at one ends of the leads 5 and 5′, a space is formed between the mold unit 8 of an LED package 9 and the substrate 3 because the stoppers 4 are seated on the substrate when the leads 5 and 5′ penetrate the substrate 3.

The heat sink 10 of the present invention is provided in the space, and heat generated by the LED device 1 is transferred to the leads 5 of the first lead frame 7 and the heat is transferred to the heat sink 10 which comes into contact with the leads 5 and then radiated.

With regard to the first and second lead frames 7 and 6 which do not have the stoppers 4 at one ends of the leads 5 and 5′, a space is artificially formed between the substrate 3 and the mold unit 8 of the LED package 9, and the heat sink is provided therein using the same method as described above.

The LED package 9 is completed by including the LED device 1, and molding the upper portions of the first and second lead frames 7 and 6 out of transparent material so that light is radiated to the outside.

The molding is generally processed using epoxy resin.

The first and second lead frames 7 and 6 are made of copper, aluminum, or iron material, and each configured to include two or more leads 5 and 5′, thereby having two electrodes, that is, the positive pole (+) and the negative pole (−).

As shown in FIG. 2, the heat sink 10 includes openings formed at locations corresponding to the respective leads 5 and 5′ so that the leads 5 and 5′ of the first and second lead frames 7 and 6 penetrate through the openings. Since the leads may vary in the extent of width, the openings are punched out in the form of longitudinal holes 11 so that all the leads can be applied.

With regard to the leads 5 and 5′ of the first and second lead frames 7 and 6 which are inserted into the longitudinal holes 11 of the heat sink 10, cut-out portions 12 each having a predetermined size are formed so that only the leads 5 of the first lead frame 7 come into contact with the heat sink 10 and the leads 5′ of the second lead frame 6 do not come into contact with the heat sink 10 in order to prevent conduction of electricity when the positive pole (+) leads come into contact with the negative pole (−) leads.

Further, the heat sink 10 includes prominences/depressions 13 provided around the side surface thereof, that is, the edge thereof, so that heat radiation area is increased, thereby increasing the speed of radiation.

Although copper (Cu), aluminum (Al) or iron (Fe), which has excellent thermal conductivity, is used as the material of the heat sink 10, any material can be used if it has excellent thermal conductivity and can be easily processed.

For example, as the material of the heat sink 10, metal material having excellent thermal conductivity, molded material which is mixed with carbon, or ceramic material having excellent thermal conductivity may be used.

The shape of the heat sink 10 may include a polygon shape which can increase the surface area, a star shape, a porous shape using porous material, a punched shape, a pipe shape, and a fiber shape depending on the purpose of use.

Further, with regards to a method of manufacturing the heat sink 10, the present invention uses a press processing method in order to manufacture the heat sink since the quality of copper (Cu) and aluminum (Al) is soft. However, the heat sink 10 may be easily manufactured using other processing methods, such as casting and sheeting, in consideration of mass productivity because of the properties of the nature of the material. A method of assembling the heat sink 10 into the LED package 9 can be made in such a way that the heat sink 10 is mounted on the surface of the substrate (for example, Printed Circuit Board (PCB)) 3 using an SMT device by manually inserting or taping the heat sink 10, and then automatically inserting an LED thereon. Therefore, the workability of assembly work does not deteriorate compared to that of existing products.

Heat generated by the LED device 1 is transferred to the heat sink 10, which has a wide radiation area, through the leads 5 of the lead frame which comes into contact with the heat sink 10, so that heat is rapidly radiated.

As described above, since heat generated by the LED device 1 is rapidly radiated, there are advantages in that the life span of each of component devices increases, in that the variation in the properties of the components attributable to heat is minimized, and in that the radiation efficiency is improved while increasing the amount of current to be applied, compared to existing pin LEDs.

A second embodiment of the present invention will be described with reference to the accompanying drawings.

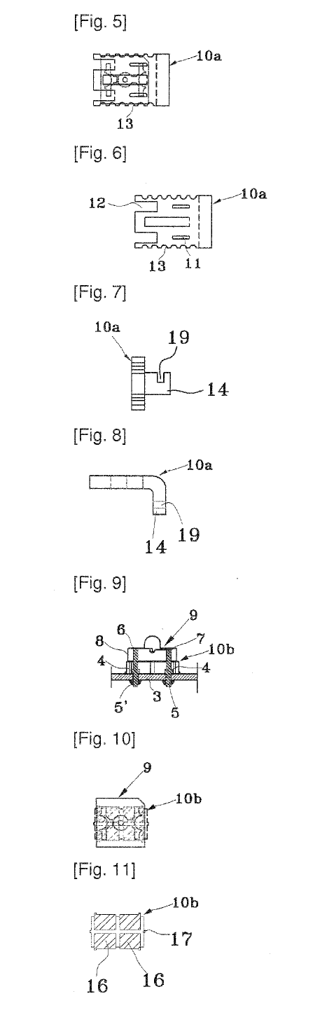

As shown in FIGS. 4 to 8, a heat sink 10a extends one end thereof and penetrates through and protrudes out from a substrate 3, thereby forming a protrusion portion 14, and includes a coupling portion 19 formed at one end of the protrusion portion 14.

The coupling portion 19 formed at the protrusion portion 14 of the heat sink 10a is coupled to a heat sink member 15 in a filling shape, a plate shape, or a slice shape.

The heat sink 10a according to the second embodiment is resined on the surface of the substrate 3 for waterproofing or in order to prevent corrosion as a method of radiating heat to a wider surface. In order to more reliably induce heat radiation, the heat sink 10a is extended to and protruded from out of the rear surface of the substrate, and the coupling portion 19 is provided so that the heat sink member 15, which is made of conductive material in a plate shape, a slice shape, or a filling shape, can be simply inserted into the protrusion portion 14, thereby rapidly radiating heat through the heat sink member 15 inserted into the coupling portion 19.

A third embodiment of the present invention will be described in detail with reference to the accompanying drawings.

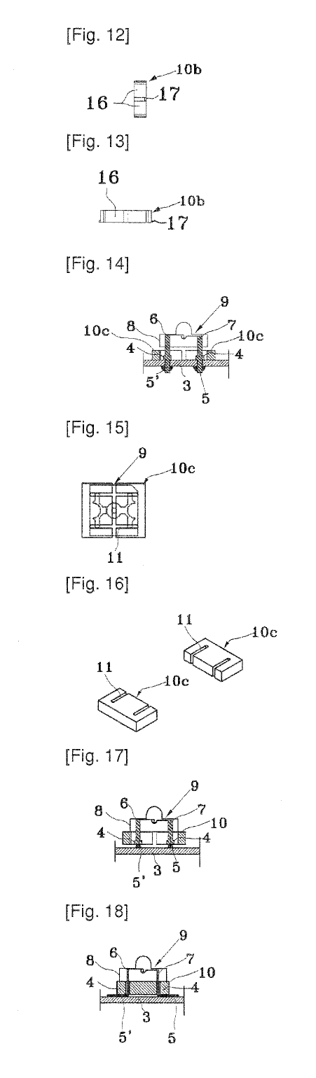

As shown in FIGS. 9 to 13, a heat sink 10b includes four heat sink slices 16 so that the terminals of the first and second lead frames 7 and 6 can independently radiate heat, and the heat sink slices 16 are divided by a non-conductive member 17. In consideration that the conduction properties of heat and electricity are the same, the leads 5 and 5′ are independently separated. For this purpose, integration is realized in such a way that plastic, which is a non-conductive substance and has a thermal conductivity coefficient of 6 W/mK and a thermal resistance of 50°, is used to prevent the conduction of electricity.

The plastic enables heat inside of the package to be lowered to 7 to 20% without using metal and the manufacture thereof is convenient.

However, since thermal resistance is too high when only plastic is used, high effectiveness cannot be expected. Therefore, materials each having high thermal conductivity are packaged and fixed, and used metal material is electrically divided so that heat can be dispersed while the electricity is not conducted.

Although the present invention uses a two-plate plastic injection molding method as a method of manufacturing the non-conduction member, the non-conductive member can be manufactured using a casting method, such as a heating-press method or a die casting method, by previously processing metal.

A fourth embodiment of the present invention will be described in detail with reference to the accompanying drawings.

As shown in FIGS. 14 to 16, two heat sinks 10c are provided so that a first lead frame 7 and a second lead frame 6 independently come into contact with respective leads 5 and 5′, and the heat sinks 10c are spaced apart from each other at a predetermined interval.

This configuration can be easily applied to the existing products in such a way that exiting LED packaging products is assembled onto a substrate and then inserted into four terminal lead frames in the size in which electricity is not conducted.

A fifth embodiment of the present invention will be described in detail with reference to the accompanying drawings.

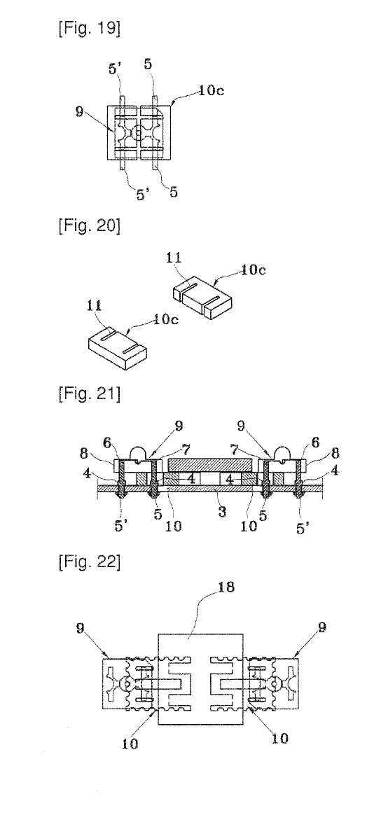

As shown in FIGS. 17 to 20, the first lead frame 7 and the second lead frame 6 are bent and extended at the bottom surface of the heat sink 10c, and mounted on the upper portion of the substrate 3 by taping it up. The purpose of this is to obtain the convenience of work for users and to meet mass production without difficulty.

A sixth embodiment of the present invention will be described in detail with reference to the accompanying drawings.

As shown in FIGS. 21 and 22, when two or more LED packages 9 are continuously arranged, heat sinks 10 are provided to face each other in order to electrically divide the leads 5 and 5′, and an insulation member 18 capable of conducting heat is provided on the heat sinks 10 which face each other. When LEDs are continuously and regularly arranged, heat can be continuously radiated by simply attaching metal having excellent thermal conductivity on the heat sinks 10 which are assembled on the substrate (PCB).

The above-described assembling method may be manually and simply performed in an insertion manner. In the case of mass production, the assembling may be realized in such a way that the heat sinks 10 are automatically inserted onto the substrate (PCB) 3, and then the LED packages 9 are automatically inserted thereinto.

As described above, when heat sinks are separately manufactured and then attached to LED packages in order to radiate heat instead of using a method of integrating heat generated from LED devices into LED packages or when existing heat sinks are integrated into LED packages, in order to overcome a spatial problem, an economic problem attributable to the rise of initial investment cost, and a compatibility-related problem such as a request for design depending on development products, the present invention enables assembling through simple insertion while products which have been manufactured in bulk by using exiting tools are used in the same way as before, and enables the size of heat sinks to be freely adjusted in consideration to thermal resistance that is inversely proportional to the area, thereby maximizing heat radiation.

The heat sink of the present invention is made of copper (Cu), aluminum (Al), or iron (Fe) which has excellent thermal and electrical conductivity in order to maximize heat radiation, and enables maximum heat radiation using leads while electricity is not conducted when the leads come into contact with each other.

Further, the heat sink of the present invention comes down to the location at which the stoppers of an existing LED exist in order to have the compatibility of being easily attached onto existing products, enables a PCB circuit to be easily designed, enables a previously designed PCB to be used without modification, minimizes the size of an opening on the PCB in order to minimize a burden of design attributable to the spatial limitation of a circuit pattern when the opening should be made on the PCB as a method of inducing to continuously radiate heat to the rear surface of the PCB, and enables continuous heat radiation by simply attaching conductive metal onto a heat emission region when LEDs are continuously arranged.

As described above, a heat sink is provided in the space between a substrate and the mold unit of an LED, so that generated heat can be effectively radiated through a first lead frame connected to an LED device, with the result that the present invention has advantages in that the life span of the LED device is extended, that variation in the properties of components attributable to heat is minimized, and that radiation efficiency is improved while increasing the amount of current to be applied as compared to an existing pin LED.

Further, the present invention is compatible with existing products, so that manufacturing costs can be greatly reduced, and the present invention has a wide application range, so that the present invention can be applied to the fields of automotive electricity and lighting, which demand high reliability.

Furthermore, the present invention can be applied to all insert-type LEDs which have a plurality of leads as well as 4-pin LEDs which are similar with the present invention.

Although the preferred embodiments of the present invention have been disclosed for illustrative purposes, those skilled in the art will appreciate that various modifications, additions and substitutions are possible, without departing from the scope and spirit of the invention as disclosed in the accompanying claims.

What is claimed is:

1. A heat-radiation structure of a pin-type power Light Emitting Diode (LED) comprising:
an LED device;
a first lead frame electrically connected to the LED device, and extended forward to an outside in order to supply power to the LED device;
a second lead frame provided to face the first lead frame, and extended forward to the outside;
a mold unit configured to include the LED device, and to mold upper portions of the first and second lead frames out of transparent material; and
a heat sink provided at a bottom of the mold unit so that the lead frames penetrate therethrough, fixed into any of the two lead frames in an insertion manner, and configured to receive heat from the lead frame which comes into contact therewith and to radiate the heat to the outside.

2. The heat-radiation structure as set forth in claim 1, wherein, when ends of the first and second lead frames are fixed to a substrate, the heat sink comprises a protrusion portion formed in such a way that one end of the heat sink is extended, penetrated through the substrate, and protruded out from a rear side of the substrate.

3. The heat-radiation structure as set forth in claim 2, further comprising a coupling portion at one end of the protrusion portion, the coupling portion being coupled to a heat sink member in a filling shape or a plate shape which is provided on the rear side of the substrate.

4. The heat-radiation structure as set forth in claim 1, wherein the heat sink comprises:
a plurality of heat sink slices respectively coupled to the first and second lead frames in the insertion manner while corresponding to the first and second lead frames; and
a non-conductive member provided between each of the heat sink slices.

5. A heat-radiation structure of a pin-type power LED comprising:
an LED device;
a first lead frame electrically connected to the LED device, and extended forward to an outside in order to supply power to the LED device;
a second lead frame provided to face the first lead frame, and extended forward to the outside;
a mold unit configured to include the LED device, and to mold upper portions of the first and second lead frames out of transparent material; and
two heat sinks each provided with longitudinal holes to which the first and second lead frames are respectively accommodated so that the first and second lead frames are inserted thereinto from both sides of a bottom of the mold unit, fixed using the respective lead frames in a state in which the two heat sinks are spaced apart from each other at a predetermined interval, and configured to receive heat from the lead frames which respectively come into contact therewith and radiate the heat to the outside.

6. The heat-radiation structure as set forth in claim 5, wherein, when ends of the first and second lead frames are fixed to a substrate, the ends of the first and second lead frames are bent and extended at a bottom of each of the heat sinks and mounted on an upper portion of the substrate.

7. The heat-radiation structure as set forth in claim 5, wherein, when two or more LED devices are arranged in a plurality of rows on the substrate, the heat sinks are provided to face each other so that the lead frames are electrically divided, and an insulation member is provided to connect two ends of the heat sinks.

8. The heat-radiation structure as set forth in claim 5, wherein each of the heat sinks is made of using any one selected from among copper, aluminum, and iron.

9. The heat-radiation structure as set forth in claim 5, wherein each of the heat sinks comprises prominences/depressions around external edge thereof in order to increase heat radiation area.

10. The heat-radiation structure as set forth in claim 1, wherein each of the heat sinks is made of using any one selected from among copper, aluminum, and iron.

11. The heat-radiation structure as set forth in claim 1, wherein each of the heat sinks comprises prominences/depressions around external edge thereof in order to increase heat radiation area.
